(19) United States
(12) Patent Application Publication
(10) Pub. No.: US 2014/0061951 A1
(43) Pub. Date: Mar. 6, 2014

(54) PACKAGE ON PACKAGE STRUCTURE AND METHOD FOR MANUFACTURING SAME

(71) Applicant: ZHEN DING TECHNOLOGY CO., LTD., Taoyuan (TW)

(72) Inventor: TAEKOO LEE, Qinhuangdao (CN)

(73) Assignee: Zhen Ding Technology Co., Ltd., Taoyuan (TW)

(21) Appl. No.: 13/756,543

(22) Filed: Feb. 1, 2013

(30) Foreign Application Priority Data
Aug. 31, 2012 (CN) 2012103179936

(51) Int. Cl. H01L 23/48; H01L 21/50

(52) U.S. Cl. CPC H01L 23/48; H01L 21/50
USPC 257/777; 438/109

(57) ABSTRACT

A method for manufacturing a package on package structure includes the step of: providing a package body comprising a first package device and a connection substrate, the first package device comprising a number of first solder pads, the connection substrate comprising a substrate main body and a number of first electrically conductive posts, the first electrically conductive posts spatially corresponding to and being connected to the first solder pads, and a solder paste printed on each first electrically conductive post; attaching a second device on the second surface of the connection substrate, thereby obtaining a stacked structure, the second package device comprising a number of second solder pads; and solidifying the solder paste on each first electrically conductive post, such that each second solder pad is soldered to the corresponding first electrically conductive post using the solder paste, thereby obtaining a package on package structure.

### BACKGROUND

1. Technical Field

The present disclosure generally relates to semiconductor package technology, and particularly to a package on package structure and a method for manufacturing the package on package structure.

2. Description of Related Art

Among the existing package structures for semiconductor, a package on package structure is one of the well-known package structures.

A typical package on package structure includes an upper package device, a lower package device, and a number of solder balls sandwiched between the upper package and the lower package device for electrically connecting the upper package device and the lower package device. However, because the pitch of the conventional solder ball is between 200 micrometers and 300 micrometers, highness of the package on package structure is higher. In addition, the temperature of the conventional package on package structure rises during thermal cycling test or actual operation, thermal stresses would easily induce in the package on package structure due to the differences of coefficient of thermal expansion (CTE) in different materials in the package on package structure, especially easily inducing warpage to the lower package device and the upper package device caused poor joints such as missing solder or cold soldering or breaking of solder balls leading to poor reliability of the package on package structure.

What is needed, therefore, is a package on package structure and a method for manufacturing the package on package structure to overcome the above-described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic, cross-sectional view of a first circuit substrate according to an exemplary embodiment.

FIG. 2 shows a photoresist layer formed on the first circuit substrate of FIG. 1.

FIG. 3 shows the photoresist layer of FIG. 2 which is patterned.

FIG. 4 shows a number of first electrically conductive posts formed on the first solder pads of the first circuit substrate exposed at the patterned photoresist layer of FIG.4, and a number of second electrically conductive posts formed on the second solder pads of the first circuit substrate exposed at the patterned photoresist layer of FIG.4.

FIG. 5 shows the patterned photoresist layer of FIG.4 removed.

FIG. 6 shows an epoxy compound layer formed on the first circuit substrate of FIG. 5.

FIG. 7 shows the epoxy compound layer of FIG. 6 being ground to obtain a substrate main body.

FIG. 8 shows solder pastes formed on the end surfaces of the exposed first and second electrically conductive posts of FIG. 6.

FIG. 9 shows a first semiconductor chip and a third semiconductor chip arranged on the first circuit substrate of FIG. 6, and a first package adhesive arranged on the third semiconductor chip to obtain a package body having the first package device.

FIG. 10 shows a second package device arranged on the package body of FIG. 9 to obtain a stacked structure.

FIG. 11 shows a package on package structure after the stacked structure has been reflowed.

### DETAILED DESCRIPTION

A package on package structure and a method for manufacturing a package on package structure and a according to embodiments will be described with reference to the drawings.

A method of manufacturing a package on package structure according to an exemplary embodiment includes the steps as follows.

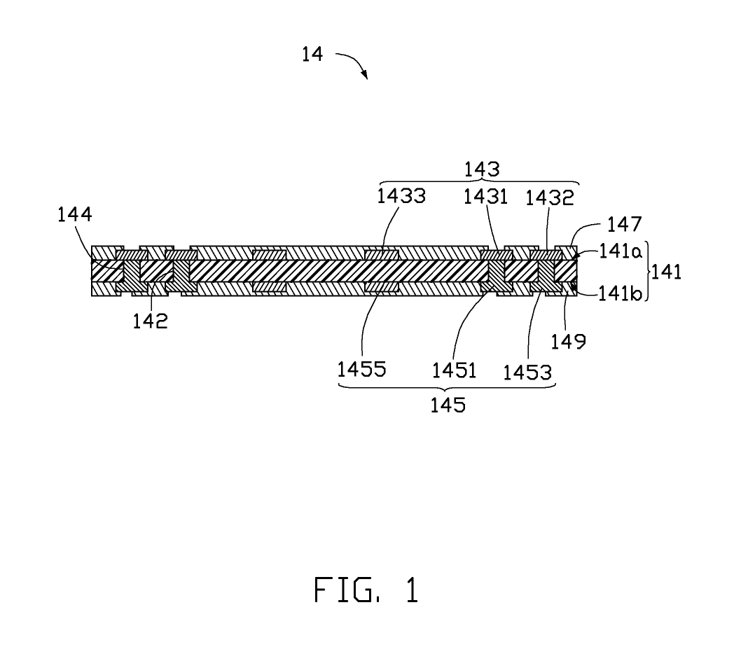

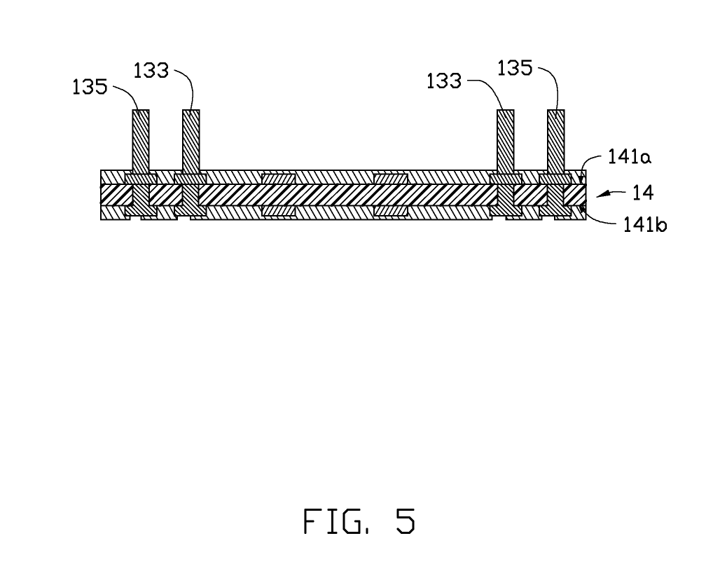

FIGS. 1 to 9 show step 1, in which a package body 10 is provided. The package body 10 includes a first package device 11 and a connection substrate 13 arranged at a side of the first package device 11.

The first package device 11 includes a first circuit substrate 14, a first semiconductor chip 15, a third semiconductor chip 16, and a first package adhesive 17. The first semiconductor chip 15 and the third semiconductor chip 16 are arranged on the first circuit substrate 14. The first package adhesive 17 is arranged on the first circuit substrate 14, and covers the first semiconductor chip 15 and the third semiconductor chip 16.

The connection substrate 13 includes a substrate main body 131, a plurality of first electrically conductive posts 133, and a plurality of second electrically conductive posts 135. The first electrically conductive posts 133 and the second electrically conductive posts 135 are arranged in the substrate main body 131. The first electrically conductive posts 133 and the second electrically conductive posts 135 have the same length.

In the present embodiment, the package body 10 may be manufactured by the following steps.

First, as FIG. 1 shows, the first circuit substrate 14 is provided. The first circuit substrate 14 may be a single-sided circuit board, a double-sided circuit board, or a multi-layered circuit board. The first circuit substrate 14 includes a first base 141, a first electrically conductive pattern 143, a second electrically conductive pattern 145, a first solder mask 147, and a second solder mask 149. In the present embodiment, the first circuit substrate 14 is a double-sided circuit board. In detail, the first base 141 has an upper surface 141a and an opposite lower surface 141b. The first electrically conductive pattern 143 is formed on the upper surface 141a, and the second electrically conductive pattern 145 is formed on the lower surface 141b. The first electrically conductive pattern 143 is electrically connected to the second electrically conductive pattern 145 by a plurality of first plated holes 142 and a plurality of second plated holes 144.

The first electrically conductive pattern 143 includes a plurality of first solder pads 1431, a plurality of third solder pads 1432, and a plurality of electrically conductive traces 1433. Each of first solder pads 1431 is arranged between the third solder pads 1432. That is, the first solder pads 1431 are surrounded by the third solder pads 1432. The first solder pads 1431 spatially correspond to the first electrically conductive posts 133, and each first solder pad 1431 is aligned with the corresponding first electrically conductive post 133. The third solder pads 1432 spatially correspond to the second electrically conductive posts 135, and each third solder pad 1432 is aligned with the corresponding second electrically conductive post 135.

The second electrically conductive pattern 145 includes a plurality of first electrical contact pads 1451, a plurality of second electrical contact pads 1453, and a plurality of electrically conductive traces 1455. Each first electrical contact pad 1451 is located between the second electrical contact pads 1453. That is, the second electrical contact pads 1453 surround the first electrical contact pad 1451. The first electrical contact pads 1451 are electrically connected to the first semiconductor chip 15. That is, the first semiconductor chip 15 is arranged on the first circuit substrate 14, and is electrically connected to the first electrical contact pads 1451 using a wire bonding process, or using a surface mounted process, or using a flip chip process, thereby electrically connecting the first semiconductor chip 15 to the first circuit substrate 14. The first electrical contact pads 1451 correspond to the first solder pads 1431, and each first electrical contact pad 1451 is aligned with the corresponding first solder pad 1431. Each first electrical contact pad 1451 is electrically connected to the corresponding first solder pad 1431 using a first plated hole 142. The second electrical contact pads 1453 are electrically connected to the second semiconductor chip 16. That is, the second semiconductor chip 16 is arranged on the first circuit substrate 14, and is electrically connected to the second electrical contact pads 1453 using a wire bonding process, or using a surface mounted process, or using a flip chip process, thereby electrically connecting the second semiconductor chip 16 to the first circuit substrate 14. The second electrical contact pads 1453 corresponds to the third solder pads 1432, and each second electrical contact pad 1453 is aligned with the corresponding third solder pad 1432. Each second electrical contact pad 1453 is electrically connected to the corresponding third solder pad 1432 using a second plated hole 144. In the present embodiment, the first semiconductor chip 15 is electrically connected to the first circuit substrate 14 using a wire bonding process, and the second semiconductor chip 16 is electrically connected to the first circuit substrate 14 using a wire bonding process.

The first solder mask 147 covers at least part of first electrically conductive pattern 143, and the upper surface 141a which is exposed at the first electrically conductive pattern 143. The first solder mask 147 protects the electrically conductive traces 1433 of the first electrically conductive pattern 143 from damage. At least part of each of the first solder pads 1431 and the third solder pads 1433 is exposed at the first solder mask 147. The second solder mask 149 covers at least part of the second electrically conductive pattern 145, and the lower surface 141b which is exposed at the second electrically conductive pattern 145. The second solder mask 149 protects the electrically conductive traces of the first electrically conductive pattern 143 from damage. At least part of each of the first electrical contact pads 1451 and the second electrical contact pads 1453 are exposed at the first solder mask 147.

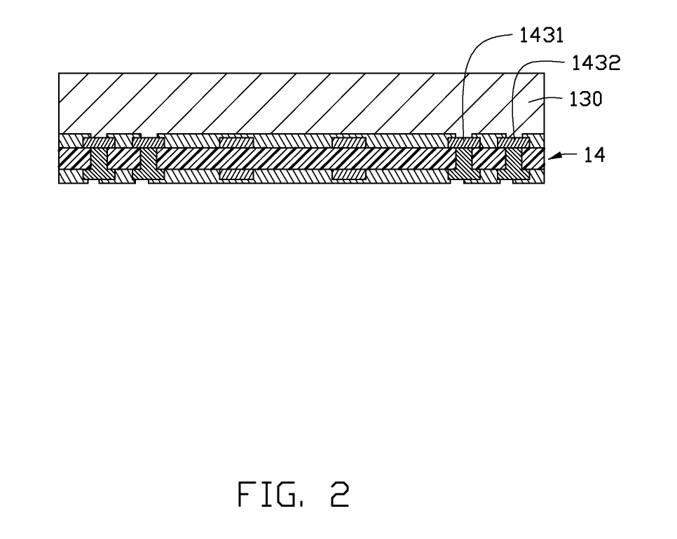

Second, as FIGS. 2 to 5 show, a first electrically conductive post 133 perpendicular to a first solder pad 1431 is formed on each first solder pad 1431, a second electrically conductive post 135 perpendicular to a third solder pad 1433 is formed on each third solder pad 1433, thereby obtaining the first electrically conductive posts 133 and the second electrically conductive posts 135. Each first electrically conductive post 133 is in contact with and electrically connected to the corresponding first solder pad 1431. Each second electrically conductive post 135 is in contact with and electrically connected to the corresponding third solder pad 1433.

In the present embodiment, the first electrically conductive posts 133 and the second electrically conductive posts 135 are manufactured by the following steps.

First, as FIG. 2 shows, a photoresist layer 130 is formed on a side of the upper surface 141a of the first circuit substrate 14. The photoresist layer 130 covers the first solder pads 1431, the third solder pads 1433, and the surface of the first circuit substrate 14 which is exposed at both the first solder pads 1431 and the third solder pads 1433. A thickness of part of the photoresist layer 131 which corresponds to the first solder pads 1431 and the third solder pads 1433, is equal to a length of the first electrically conductive post 133.

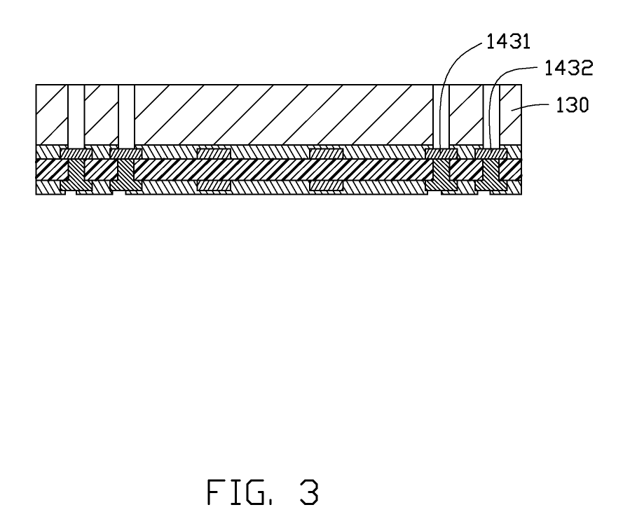

Second, as FIG. 3 shows, the photoresist layer 130 is selectively exposed and developed to form a photoresist layer 130 which is patterned, thereby exposing at least part of each of the first solder pads 1431 and the third solder pads 1433.

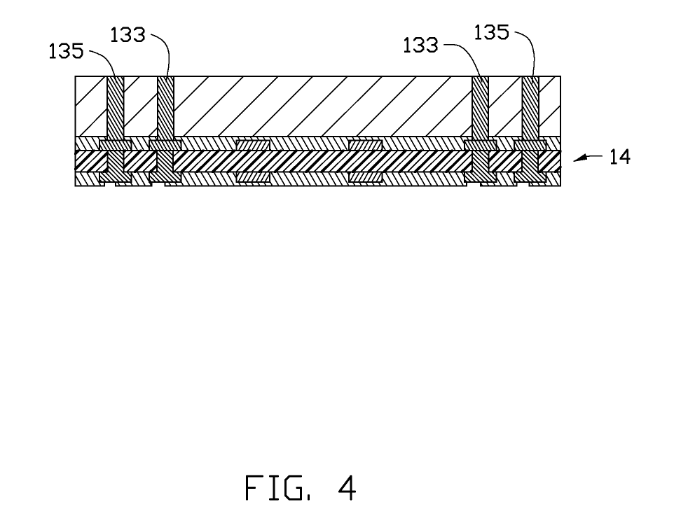

Third, as FIG. 4 shows, a first electrically conductive post 133 is formed on each first solder pad 1431 using an electroplating process, and a second electrically conductive post 135 is formed on each third solder pad 1433 by the same process.

Finally, as FIG. 4 shows, the patterned photoresist layer 130 is removed from the circuit substrate 14, thereby obtaining the first electrically conductive posts 133 and the third electrically conductive posts 135.

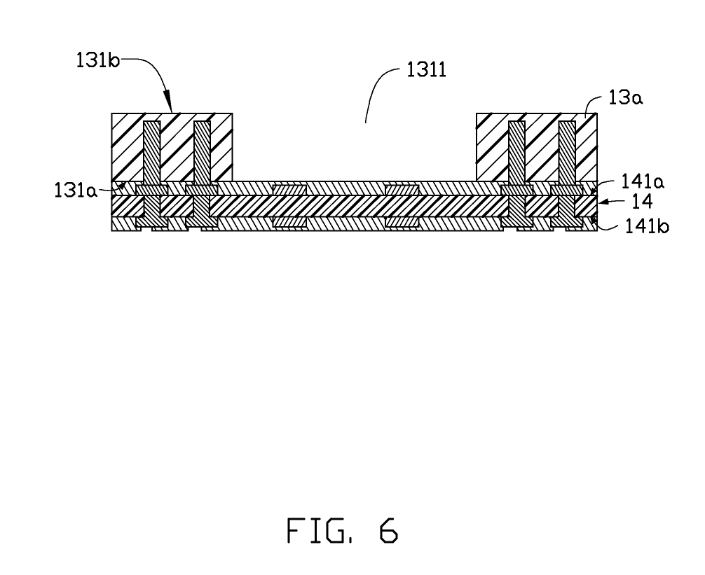

Third, as FIG. 6 shows, a molding compound layer 13a is laminated onto a side of the solder mask 147 of the first circuit substrate 14 using a molding process. The molding compound layer 13a covers the first electrically conductive posts 133, the second electrically conductive posts 135, and the surface of the solder mask 147 of the first circuit substrate 14 which is exposed at both the first electrically conductive posts 133 and the second electrically conductive posts 135. In detail, the molding compound layer 13a has a first surface 131a and an opposite second surface 131b. After lamination, the first surface 131a is adhered to the solder mask 147 of the first circuit substrate 14.

In the present embodiment, the molding compound layer 13a defines a receiving hole 1311. The receiving hole 1311 passes through the first surface 131a and the second surface 131b. The first electrically conductive posts 133 surround the receiving hole 1311. The second electrically conductive posts 135 surround the first electrically conductive posts 133. In the present embedment, a material of the molding compound layer 13a is sheet molding compound, and the first surface 131a is parallel with the upper surface 141a.

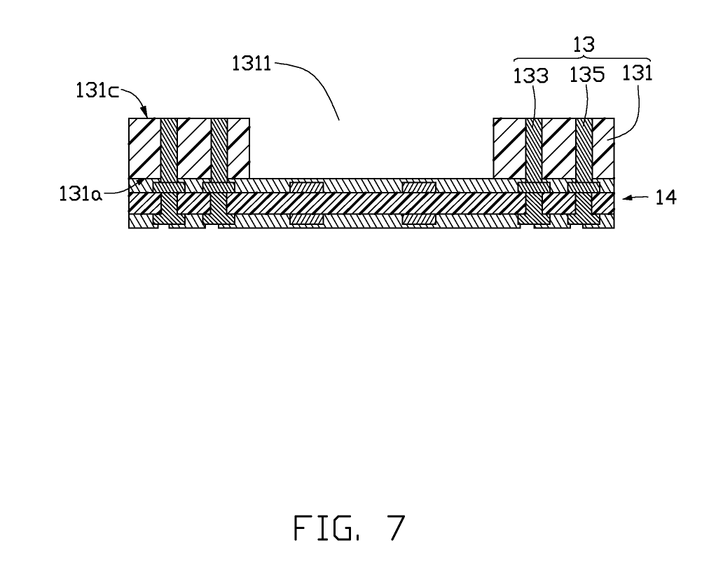

Four, as FIG. 7 shows, the molding compound layer 13a is ground using a grinding process, such that the distal ends of both the first and second electrically conductive posts 133, 135 which are furthest from the first circuit substrate 14 are exposed at the ground molding compound layer 13a. In the present embodiment, the distal end surfaces of both the first and second electrically conductive posts 133, 135 which are furthest from the first circuit substrate 14 are coplanar with the surface of the ground molding compound layer 13a furthest from the first circuit substrate 14. The ground molding compound layer 13a is considered as the substrate main body 131. The first surface 131a of the molding compound layer 13a is considered as the first surface of the substrate main body 131. The surface of the ground molding compound layer 13a furthest from the first circuit substrate 14 is considered as the second surface 131c of the substrate main body 131. The receiving hole 1311 is considered as the receiving hole of the substrate main body 131. The substrate main body 131, the first electrically conductive posts 133, and the second electrically conductive posts 135 cooperatively constitute the connection substrate 13.

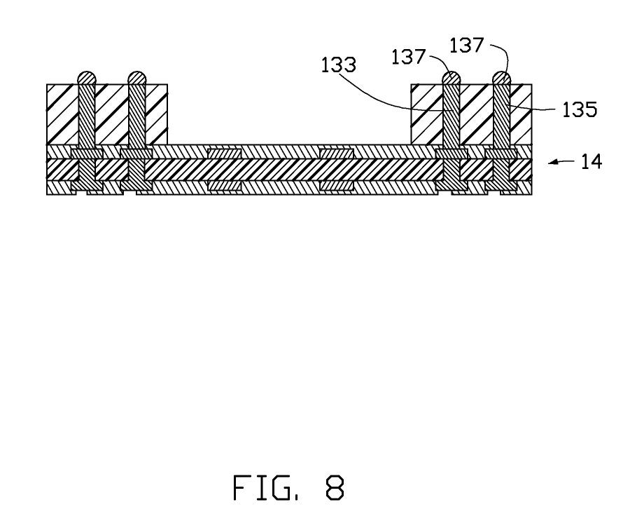

Five, as FIG. 8 shows, a solder paste 137 is printed on the distal end of each of the first and second electrically conductive posts 133, 135 furthest from the first circuit substrate 14 using a printing method.

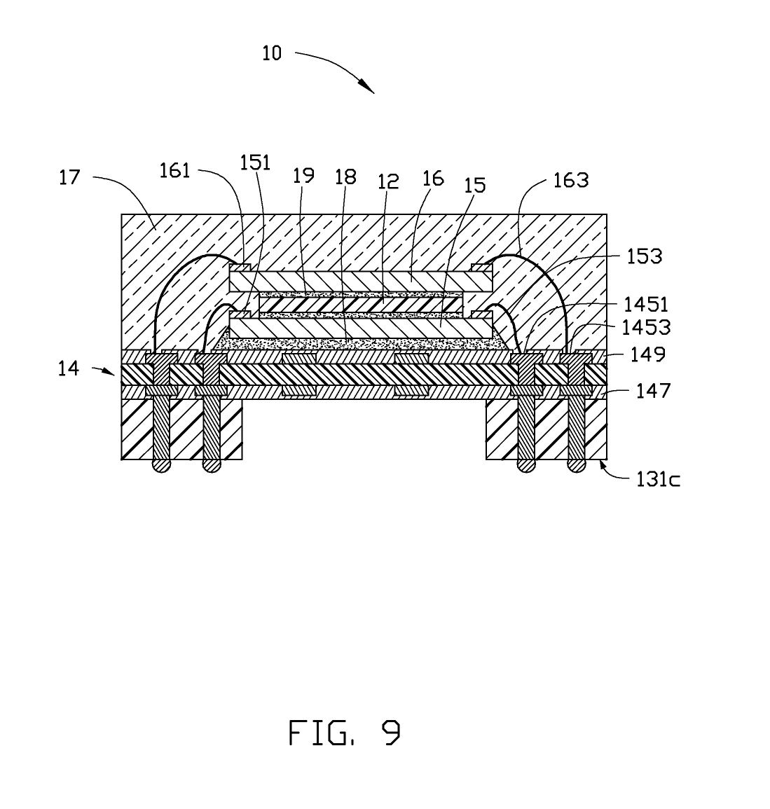

Finally, as FIG. 9 shows, the first semiconductor chip 15 and the second semiconductor chip 16 are arranged on the side of the first circuit substrate 14 furthest from the connection substrate 13, and the first semiconductor chip 15 is sandwiched between the second semiconductor chip 16 and the circuit substrate 14. The first semiconductor chip 15 may be a memory chip, a logic chip, or a digital chip. In the present embodiment, the first semiconductor chip 15 is a logic chip. The first semiconductor chip 15 is adhered to the surface of the second solder mask 149 furthest from the first base 141 via a first insulation adhesive layer 18, and is electrically connected to the circuit substrate 14 using a wire bonding process. The first semiconductor chip 15 includes a plurality of third electrical contact pads 151 corresponding to the first electrical contact pads 1451. Each third electrical contact pad 151 is electrically connected to the corresponding first electrical contact pad 1451 using a first electrically conductive wire 153 (e.g. gold wire). The second semiconductor chip 16 may be a memory chip, a logic chip, or a digital chip. In the present embodiment, the second semiconductor chip 16 is a memory chip. The second semiconductor chip 16 is adhered to the surface of the first semiconductor chip 15 furthest from the first circuit substrate 14 using a second insulation adhesive layer 19, and is electrically connected to the circuit substrate 14 using a wire bonding process. The second semiconductor chip 16 includes a plurality of fourth electrical contact pads 161 corresponding to the second electrical contact pads 1453. Each fourth electrical contact pad 161 is electrically connected to the corresponding second electrical contact pad 1453 using a second electrically conductive wire 163 (e.g. gold wire).

Preferably, in order to prevent signal interference between the first and second semiconductor chips 15, 16, a separation sheet 12 is sandwiched between the first and second semiconductor chips 15, 16. That is, the separation sheet 12 is arranged in the second insulation adhesive layer 19. In other embodiments, the separation sheet 12 may be omitted. Then, the first package adhesive 17 is arranged on the side of the circuit substrate 14 furthest from the connection substrate 13 to obtain the package body 10. The first circuit substrate 14, the first semiconductor chip 15, the third semiconductor chip 16 and the first package adhesive 17 cooperatively constitute the first package device 11. The first package adhesive 17 covers the first semiconductor chip 15, the third semiconductor chip 16, and the surface of the first circuit substrate 14 exposed at the first and third semiconductor chips 15, 16, thereby protecting the first and third semiconductor chips 15, 16 from damage. A material of the first package adhesive 17 is epoxy molding compound. In the present embodiment, an area of a cross-section of the first package adhesive 17 taken in a plane parallel with the upper surface 141a of the first circuit substrate 14 is the same as an area of a cross-section of the first circuit substrate 14 taken in a plane parallel with the upper surface 141a of the first circuit substrate 14.

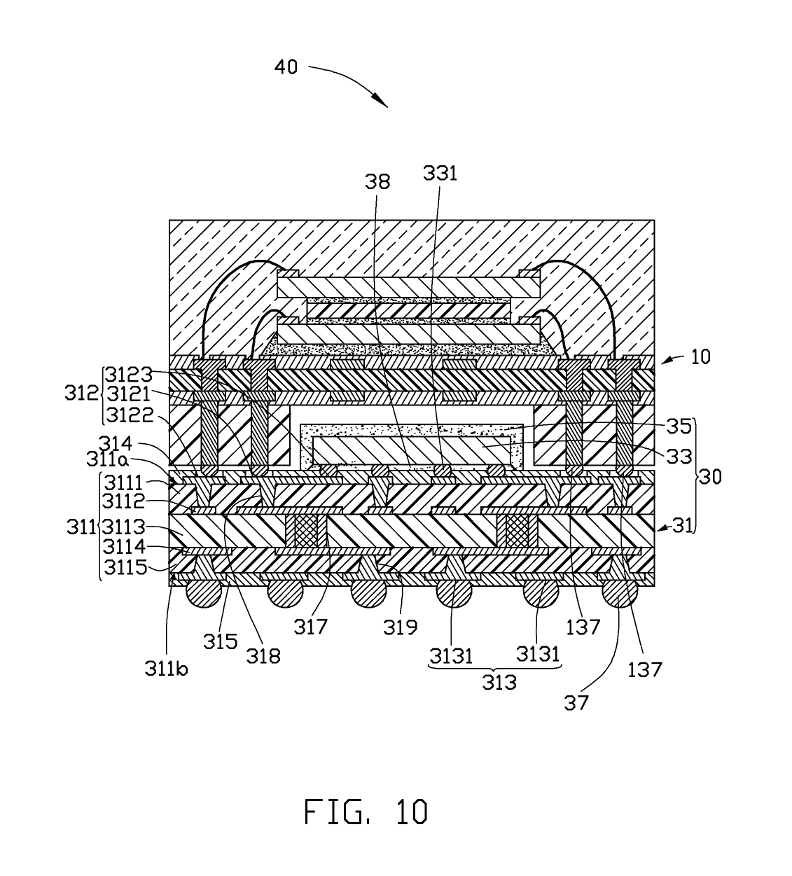

FIG. 10 shows step 2, in which a second package device 30 is attached on a side of the second surface 131 of the package body 10.

The second package device 30 includes a second circuit substrate 31, a second semiconductor chip 33 arranged on the second circuit substrate 31, and a second package adhesive 35 arranged on the second circuit substrate 31 and covering the second semiconductor chip 33.

The second circuit substrate 31 may be a single-sided circuit board, a double-sided circuit board, or a multi-layered circuit board. The second circuit substrate 31 includes a second base 311, a third electrically conductive pattern 312, a fourth electrically conductive pattern 313, a third solder mask 314, and a fourth solder mask 315. In the present embodiment, the second circuit substrate 31 is a four-layer circuit board, and there are two electrically conductive pattern layers in the second base 311.

The second base 311 includes a first insulation layer 3111, a first electrically conductive pattern layer 3112, a second insulation layer 3113, a second electrically conductive pattern layer 3114, and a third insulation layer 3115. The first electrically conductive pattern layer 3112 and the second electrically conductive pattern layer 3114 are formed on the opposite surfaces of the second insulation layer 3113. The first electrically conductive pattern layer 3112 is electrically connected to the second electrically conductive pattern layer 3114 using at least one third plated hole 317. The first insulation layer 3111 covers the first electrically conductive pattern layer 3112. A surface of the first insulation layer 3111 furthest from the second insulation layer 3113 is considered as the upper surface 311a of the second base 311. The third insulation layer 3115 covers the second electrically conductive pattern layer 3114. A surface of the third insulation layer 3115 furthest from the second electrically conductive pattern layer 3114 is considered as the lower surface 311b of the second base 311.

The third electrically conductive pattern 312 is formed on the upper surface 311a of the second circuit substrate 311, and is electrically connected to the first electrically conductive pattern layer 3112 using at least one fourth plated hole 318. The third electrically conductive pattern 312 includes a plurality of second solder pads 3121, a plurality of fourth solder pads 3122, a plurality of fifth solder pads 3123, and a plurality of electrically conductive traces (not shown). Each of the second solder pads 3121 is arranged between the fourth solder pads 3122. That is, the fourth solder pads 3122 surround the second solder pads 3121. Each of the fifth solder pads 3123 is arranged between the second solder pads 3121. That is, the second solder pads 3121 surround the fifth solder pads 3123. The second solder pads 3121 spatially correspond to the first electrically conductive posts 133, and each second solder pad 3121 is nearest the solder paste 137 on the corresponding first electrically conductive post 133, such that the first semiconductor chip 15 is electrically connected to the second circuit substrate 31 using the first electrically conductive posts 133 and the solder paste 137 on the first electrically conductive posts 133. The fourth solder pads 3122 spatially correspond to the second electrically conductive posts 135, and each fourth solder pad 3122 is nearest the solder paste 137 on the corresponding second electrically conductive post 135, such that the third semiconductor chip 16 is electrically connected to the second circuit substrate 31 using the second electrically conductive posts 135 and the solder paste 137 which is on the second electrically conductive posts 135. The third solder mask 314 covers at least part of the electrically conductive traces of the third electrically conductive pattern 312 and the upper surface 311a exposed at the third electrically conductive pattern 312, and itself exposes the second solder pads 3121, the fourth solder pads 3122, and the fifth solder pads 3123. The third solder mask 314 protects the electrically conductive traces of the third electrically conductive pattern 312 from damage.

The fourth electrically conductive pattern 313 is formed on the lower surface 211b of the second circuit substrate 311, and is electrically connected to the second electrically conductive pattern layer 3114 using at least one seventh plated hole 319 in the third insulation layer 3115. The fourth electrically conductive pattern 313 includes a plurality of sixth solder pads 3131. The fourth solder mask 315 covers at least part of the fourth electrically conductive pattern 313 and the lower surface 311b exposed at the fourth electrically conductive pattern 313, and itself exposes the sixth solder pads 3131. A plurality of solder balls 37 are formed on the exposed solder pads 3131. The solder balls 37 on the exposed solder pads 3131 are configured for electrically connecting the second circuit substrate 31 to another circuit board or other electronic elements.

The second semiconductor chip 33 may be a memory chip, a logic chip, or a digital chip. In the present embodiment, the second semiconductor chip 33 is a logic chip. The second semiconductor chip 33 is adhered to the surface of the third solder mask 314 using a third insulation adhesive layer 38, and is electrically connected to the fifth solder pads 3123 using a wire bonding process, using a surface mounted process, or using a flip chip process. In the present embodiment, the second semiconductor chip 33 is packaged on the second circuit substrate 31 using a flip chip process. The second semiconductor chip 33 is electrically connected to the fifth solder pads 3123 using solder bumps 331.

The second package adhesive 35 is attached on the third solder mask 314 of the second circuit substrate 31, and covers the second semiconductor chip 33 to protect the second semiconductor chip 33 from damage. The second package adhesive 35 may be attached on the third solder mask 314 using a printing process or using a molding process. An area of a cross-section of the second package adhesive 35 taken in a plane parallel with the upper surface 311a is larger than an area of a cross-section of the second semiconductor chip 33 taken in a plane parallel with the upper surface 311a, and is smaller than an area of a cross-section of the receiving hole 1311 taken in a plane parallel with the upper surface 141a, thereby covering the second semiconductor chip 33 with the second package adhesive 35 received in the receiving hole 1311. A material of the second package adhesive 35 may be epoxy molding compound.

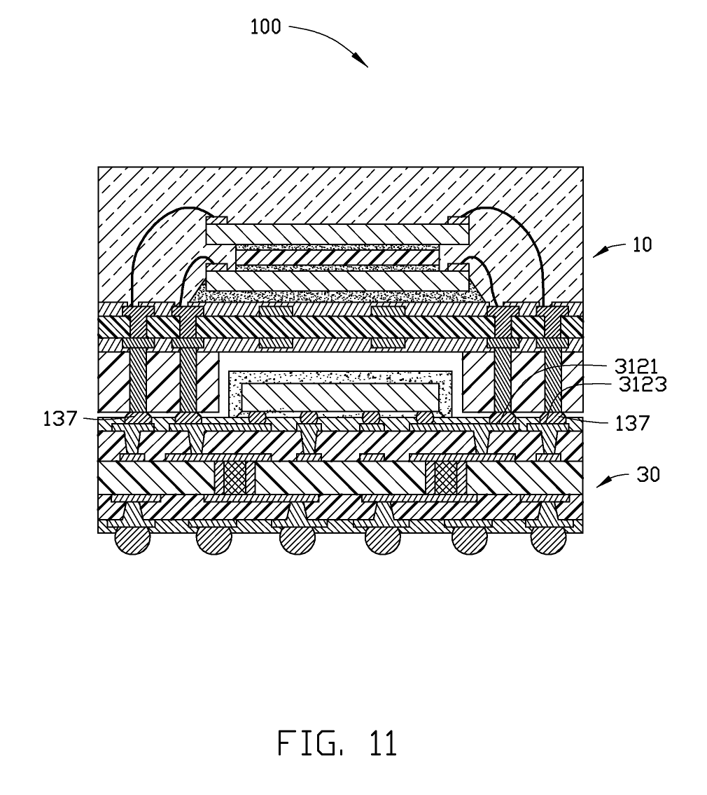

FIG. 11 shows step 3, in which the solder pastes 137 of the stacked structure 40 are reflowed to melt, and then are solidified, thereby soldering the ends of the first electrically conductive posts 133 which have solder paste 137 printed thereon to the second solder pads 3121 using the solder paste 137 on the first electrically conductive posts 133, and soldering the ends of the second electrically conductive posts 135 which have solder paste 137 printed thereon to the fourth conductive posts 3122 using the solder paste 137 on the second electrically conductive posts 135. Accordingly, the package on package structure 100 is obtained.

The package on package structure 100 includes the connection substrate 10, the first package device 21 being arranged on one side of the connection substrate 10, and the second package device 30 being arranged on the other side of the connection substrate 10. The first package device 11 includes the first circuit substrate 14, the first semiconductor chip 15, and the third semiconductor chip 16. The first semiconductor chip 15 and the third semiconductor chip 16 are arranged on the first circuit substrate 14. The first circuit substrate 14 includes the first solder pads 1431 and the third solder pads 1432. The first solder pads 1431 and the third solder pads 1432 are arranged at the same side of the first circuit substrate 14, and the third solder pads 1432 surround the first solder pads 1431. The first solder pads 1431 are electrically connected to the first semiconductor chip 15, and the third solder pads 1432 are electrically connected to the third semiconductor chip 16. The connection substrate 13 includes a substrate main body 131, the first electrically conductive posts 133, and the second electrically conductive posts 135. The first electrically conductive posts 133 and the second electrically conductive posts 135 are arranged in the substrate main body 131. The substrate main body 131 has the first surface 131a and the second surface 131c. The first surface 131a is adhered to the surface of the first circuit substrate 14 on which the first solder pads 1431 are formed. The second electrically conductive posts 135 surround the first electrically conductive posts 133, and each of the first electrically conductive posts 133 and the second electrically conductive posts 135 passes through the first surface 131a and the second surface 131b. The first electrically conductive posts 133 spatially correspond to the first solder pads 1431, and an end of each first electrically conductive post 133 nearest to the first surface 131a is in contact with and electrically connected to the corresponding first solder pad 1431. A solder paste 137 is printed on the distal end surface of each first electrically conductive post 133 nearest to the second surface 131b. The second electrically conductive posts 135 spatially correspond to the third solder pads 1432, and an end of each second electrically conductive post 135 nearest to the first surface 131a is in contact with and electrically connected to the corresponding third solder pad 1432. A solder paste 137 is printed on an end surface of each second electrically conductive post 135 nearest to the second surface 131b. The second package device 30 includes the second circuit substrate 31 and the second semiconductor chip 33 arranged on the second circuit substrate 31. The second circuit substrate 31 includes the second solder pads 3121 and the fourth solder pads 3122. The second solder pads 3122 and the fourth solder pads 3122 are exposed at the same side of the second circuit substrate 31. The second solder pads 3121 spatially correspond to the first electrically conductive posts 133, and each second solder pad 3121 is soldered to an end of the corresponding first electrically conductive post 133 nearest to the second surface 131b using a solder paste 137 printed on the corresponding first electrically conductive post 133. The fourth solder pads 3122 spatially correspond to the second electrically conductive posts 135, and each fourth solder pad 3122 is soldered to an end of the corresponding second electrically conductive post 135 nearest to the second surface 131b using a solder paste 137 printed on the corresponding second electrically conductive post 133, such that the second package device 30 is soldered to the second surface 131c of the connection substrate 13.

In the package on package structure 100, the connection substrate 13 is laminated onto the first package device 11, and the connection substrate 13 is attached to the second package device 30 using solder paste 137 on the first and second electrically conductive posts 133, 135 in the connection substrate 13. Accordingly, the first package device 11 is connected to the second package device 30 using the connection substrate 13, not using the solder balls. The rate of finished product of the package on package structure 100 is thus significantly improved. In addition, the method for manufacturing the package on package structure 100 is very simple, and the cost of the method is much lower.

In other embodiments, there may be another package device arranged on the surface of the first package adhesive 17 furthest from the connection substrate 13, and there may be another package device arranged on the surface of the second package device 30 furthest from the connection substrate 13, thereby obtaining a package on package structure having three package devices, four package devices, or more than four package devices.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a package on package structure, comprising:
providing a package body, the package body comprising a first package device and a connection substrate attached on the first package device, the first package device comprising a first circuit substrate and a first semiconductor chip arranged on the first circuit substrate, the first circuit substrate comprising a plurality of first solder pads, the connection substrate comprising a substrate main body and a plurality of first electrically conductive posts arranged in the substrate main body, the substrate main body having a first surface and an opposite second surface, the first surface adhered to the surface of the first circuit substrate on which the first solder pads are formed, the first electrically conductive posts spatially corresponding to the first solder pads, an end of each first electrically conductive post nearest to the first surface being in contact with and electrically connected to the corresponding first solder pad, and a solder paste being printed on an end surface of each first electrically conductive post exposed at the second surface;
attaching a second device on the second surface of the connection substrate, thereby obtaining a stacked structure, the second package device comprising a second circuit substrate and a second semiconductor chip arranged on the second circuit substrate, the second circuit substrate comprising a plurality of second solder pads, the second solder pads corresponding to the first electrically conductive posts, the second solder pads aligned with the corresponding first electrically conductive post, and each second solder pad being arranged adjacent to a solder paste printed on the corresponding first electrically conductive post; and
solidifying the solder paste on each first electrically conductive post, such that each second solder pad is soldered to the corresponding first electrically conductive post using the solder paste, thereby obtaining a package on package structure.

2. The method of claim 1, wherein the first package device and the first solder pads are arranged at the opposite sides of the first circuit substrate, a method for manufacturing the package body comprising:
providing the first circuit substrate;
forming one first electrically conductive post on the corresponding first solder pad, thereby obtaining the first electrically conductive posts, each first electrically conductive post being in contact with and electrically connected to the corresponding first solder pad;
laminating the molding compound layer on the side of the first solder pads of the first circuit substrate, the molding compound layer covering the first electrically conductive posts and the surface of the first circuit substrate which is exposed at the first electrically conductive posts;
grinding the molding compound layer, such that one end surface of each first electrically conductive post furthest the first circuit substrate is exposed at the ground molding compound layer, the ground epoxy molding compound being the substrate main body, the substrate main body and the first electrically conductive posts cooperatively constituting the connection substrate;
printing a solder paste on the end surface of each electrically conductive post furthest from the first circuit substrate, thereby obtaining a semi-finished package on package; and
arranging the first semiconductor chip on the side of the first circuit substrate furthest from the connection substrate, thereby obtaining the package body.

3. The method of claim 2, wherein the step of forming a first electrically conductive post on the corresponding first solder pad, comprises:
forming a photoresist layer on a side of the first solder pads of the first circuit substrate, the photoresist layer covering the first solder pads and the surface of the first circuit substrate which is exposed at the first solder pads;
exposing and developing the photoresist layer to form a patterned photoresist layer, thereby exposing the first solder pads;
forming a first electrically conductive post on each first solder pad using an electroplating process; and
removing the patterned photoresist layer from the first circuit substrate.

4. The method of claim 2, wherein the first semiconductor chip and the first solder pads are arranged at the opposite sides of the first circuit substrate; the first circuit substrate comprises a plurality of first electrical contact pads, the first electrical contact pads and the first solder pads are arranged at the opposite sides of the first circuit substrate, and the first electrical contact pads surround the first semiconductor chip, the first electrical contact pads corresponds to the first solder pads, each first electrical contact pad is electrically connected to the corresponding first solder pad using a first plated hole, when the first semiconductor chip is arranged on the first circuit substrate, the first semiconductor chip is electrically connected to the first circuit substrate using the first electrical contact pads.

5. The method of claim 2, wherein after arranging the first semiconductor chip on the side of the first circuit substrate furthest from the connection substrate, the method further comprises a step of attaching a first package adhesive on the first circuit substrate, the first package adhesive covers the first semiconductor chip.

6. The method of claim 1, wherein the substrate main body defines a receiving hole, the receiving hole passes through the first surface and the second surface, the first electrically conductive posts surround the receiving hole; the second semiconductor chip and the second solder pads are arranged at the same side of the second circuit substrate, and the second solder pads surround the second semiconductor chip, when the second package device is arranged on the connection substrate, the second semiconductor chip is received in the receiving hole.

7. A method for manufacturing a package on package structure, comprising:
providing a package body, the package body comprising a first package device and a connection substrate attached on the first package, the first package device comprising a first circuit substrate, a first semiconductor chip arranged on the first circuit substrate, and a third semiconductor chip arranged on the first circuit substrate, the first circuit substrate comprising a plurality of first solder pads and a plurality of third solder pads, the first solder pads and the third solder pads being arranged at the same side of the first circuit substrate, the third solder pads surrounding the first solder pads, the first solder pads being electrically connected to the first semiconductor chip, the second solder pads being electrically connected to the second semiconductor chip, the connection substrate comprising a substrate main body, a plurality of first electrically conductive posts arranged in the substrate main body, and a plurality of second electrically conductive posts arranged in the substrate main body, the substrate main body having a first surface and an opposite second surface, the first surface adhered to the surface of the first circuit substrate on which the first solder pads are formed, and each of the first and second electrically conductive posts passing through the first surface and the second surface, the first electrically conductive posts corresponding to the first solder pads, an end of each first electrically conductive post nearest to the first surface being in contact with and electrically connected to the corresponding first solder pad, and a solder paste being printed on an end surface of each first electrically conductive post nearest to the second surface, the second electrically conductive posts corresponding to the third solder pads, an end of each second electrically conductive post nearest to the first surface being in contact with and electrically connected to the corresponding third solder pad, and a solder paste being printed on an end surface of each second electrically conductive post nearest to the second surface;
attaching a second package device on the second surface of the connection substrate, thereby obtaining a stacked structure, the second package device comprising a second circuit substrate and a second semiconductor chip arranged on the second circuit substrate, the second circuit substrate comprising a plurality of second solder pads and a plurality of fourth solder pads, the second and fourth solders pads being arranged at the same side of the second circuit substrate, the second solder pads corresponding to the first electrically conductive posts, each second solder pad being arranged adjacent to the solder paste printed on the corresponding first electrically conductive post, the fourth solder pads corresponding to the second electrically conductive posts, and each fourth solder pad being arranged adjacent to the solder paste printed on the corresponding second electrically conductive post; and
solidifying the solder paste on each of the first electrically conductive posts and the second electrically conductive posts, such that each second solder pad is soldered to the corresponding first electrically conductive post using the solder paste on the corresponding first electrically conductive post, and each fourth solder pad is soldered to the corresponding second electrically conductive post using the solder paste on the corresponding second electrically conductive post, thereby obtaining a package on package structure.

8. The method of claim 7, wherein the first semiconductor chip is sandwiched between the third semiconductor chip and the first circuit substrate, the first semiconductor chip and the first solder pads are arranged at the opposite sides of the first circuit substrate, the second electrically conductive posts surrounds the first electrically conductive posts; the substrate main body defines a receiving hole passing through the first surface and the second surface, the first electrically conductive posts surround the receiving hole, the second electrically conductive posts surround the first electrically conductive post; the second semiconductor chip, the second solder pads, and the fourth solder pads are arranged at the same side of the second circuit substrate, the fourth solder pads surround the second solder pads, the second solder pads surround the second semiconductor chip; when the second package device is attached on the connection substrate, the second semiconductor chip is received in the receiving hole.

9. The method of claim 7, wherein the first package device and the first solder pads are arranged at the opposite sides of the first circuit substrate, the first semiconductor chip is sandwiched between the third semiconductor chip and the first circuit substrate, a method for manufacturing the package body comprising:
providing the first circuit substrate;
forming a first electrically conductive post on the corresponding first solder pad, and a second electrically conductive post on the corresponding third solder pad, thereby obtaining the first electrically conductive posts and the second electrically conductive posts, each first electrically conductive post being in contact with and electrically connected to the corresponding first solder pad, each second electrically conductive post being in contact with and electrically connected to the corresponding third solder pad;
laminating the molding compound layer on a side of the first solder pads of the first circuit substrate, the molding compound layer covering the first electrically conductive posts, the second electrically conductive posts and the surface of the first circuit substrate exposed at both the first electrically conductive posts and the second electrically conductive posts;
grinding the molding compound layer, such that the end surfaces of both the first electrically conductive posts and the second electrically conductive posts furthest from the first circuit substrate are exposed at the ground molding compound layer, the substrate main body, the first electrically conductive posts, and the second electrically conductive posts cooperatively defining the connection substrate;
printing a solder paste on one end surface of each of both the first electrically conductive posts and the second electrically conductive posts furthest from the first circuit substrate, thereby obtaining a semi-finished package on package; and
arranging the first semiconductor chip and the third semiconductor chip on the side of the first circuit substrate furthest from the connection substrate, and the first semiconductor chip being sandwiched between the first circuit substrate and the third semiconductor chip, thereby obtaining the package body.

10. The method of claim 9, wherein the step of forming a first electrically conductive post on the corresponding first solder pad, and a second electrically conductive post on the corresponding third solder pad, comprises:
forming a photoresist layer on a side of the first solder pads of the first circuit substrate, the photoresist layer covering the first solder pads, the third solder pads, and the surface of the first circuit substrate exposed at both the first solder pads and the third solder pads;
exposing and developing the photoresist layer to form a patterned photoresist layer, thereby exposing the first solder pads and the second solder pads;
forming a first electrically conductive post on each first solder pad using an electroplating process, and forming a second electrically conductive post on each third solder pad using an electroplating process; and
removing the patterned photoresist layer from the first circuit substrate.

11. A package on package structure, comprising:
a package body, the package body comprising a first package device and a connection substrate attached on the first package, the first package device comprising a first circuit substrate and a first semiconductor chip arranged on the first circuit substrate, the first circuit substrate comprising a plurality of first solder pads, the connection substrate comprising a substrate main body and a plurality of first electrically conductive posts arranged in the substrate main body, the substrate main body having a first surface and an opposite second surface, the first surface adhered to the surface of the first circuit substrate on which the first solder pads are formed, the first electrically conductive posts corresponding to the first solder pads, one end of each first electrically conductive post nearest to the first surface being in contact with and electrically connected to the corresponding first solder pad, and a solder paste being printed on one end surface of each first electrically conductive post nearest to the second surface; and
a second package device, the second package device comprising a second circuit substrate and a second semiconductor chip arranged on the second circuit substrate, the second circuit substrate comprising a plurality of second solder pads, the second solder pads corresponding to the first electrically conductive posts, and each second solder pad being soldered to one end surface of the corresponding first electrically conductive nearest to the second surface using the solder paste printed on the corresponding first electrically conductive post, thereby making the second package device soldered at the side of the second surface of the connection substrate.

12. The package on package structure of claim 11, wherein the first package device further comprises a first package adhesive covering the first semiconductor chip, an area of a cross-section of the first package adhesive taken in a plane parallel with the first surface of the substrate main body is equal to an area of a cross-section of first circuit substrate taken in a plane parallel with the first surface of the substrate main body, the first semiconductor chip and the first solder pads are arranged at the opposite sides of the first circuit substrate.

13. The package on package structure of claim 11, wherein the substrate main body defines a receiving hole, the receiving hole passes through the first surface and the second surface, the first electrically conductive posts surround the receiving hole, the second semiconductor chip and the second solder pads are arranged at the same side of the second circuit substrate, the second semiconductor chip is received in the receiving hole, the second solder pads surrounds the second semiconductor chip.

14. The package on package structure of claim 11, wherein the second circuit substrate has an upper surface and an opposite lower surface, the second semiconductor chip further comprises a second package adhesive, an area of a cross-section of the second package adhesive taken in a plane parallel with the upper surface of the second circuit substrate is larger than an area of a cross-section of the second semiconductor chip taken in a plane parallel with the upper surface the upper surface of the second circuit substrate, and is smaller than an area of a cross-section of the receiving hole taken in a plane parallel with the first surface of the substrate main body.
